(19) United States
(12) Patent Application Publication
(10) Pub. No.: US 2008/0014755 A1
(43) Pub. Date: Jan. 17, 2008

(54) PLASMA ETCHING METHOD AND COMPUTER-READABLE STORAGE MEDIUM

(75) Inventors: Nobuhiro WADA, Nirasaki-shi (JP); Hikoichiro Sasaki, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/773,232

(22) Filed: Jul. 3, 2007

Related U.S. Application Data
(60) Provisional application No. 60/832,131, filed on Jul. 21, 2006.

(30) Foreign Application Priority Data
Jul. 12, 2006 (JP) 2006-191704

(51) Int. Cl. H01L 21/3065

(52) U.S. Cl. 438/717; 156/345.24; 257/E21.214

(57) ABSTRACT

In a plasma etching method, a plasma of a processing gas containing CₓF_{y} (x, y are integers equal to or greater than 1), a rare gas and O₂ by applying a high frequency power to the upper or the lower electrode while the processing gas is being supplied into the processing chamber. Further, an oxide film formed on the substrate is etched through a mask layer while applying a high frequency power for bias to the lower electrode. When a certain etching condition is likely to cause a low etching opening characteristic, a DC voltage is applied to the upper electrode, to thereby obtain a fine opening characteristic.

### FIELD OF THE INVENTION

The present invention relates to a plasma etching of an oxide film, i.e., an adequate plasma etching method for, e.g., a high aspect ratio contact (HARC) process, and also relates to a computer-readable storage medium for storing therein a control program for use in executing the plasma etching method.

### BACKGROUND OF THE INVENTION

In a manufacturing process of a semiconductor device, a photoresist pattern is formed on a semiconductor wafer, which is a substrate to be processed, through a photolithography process to be used as a mask in etching of the semiconductor wafer.

Recently, with a trend of miniaturization of semiconductor devices, etching also requires microprocessing. For example, in an HARC process, an aspect ratio of a hole or a trench formed in an oxide film is getting increased, and for the reason, a comparatively high selectivity and a fine opening characteristic are required for the etching of the oxide film.

To meet such a requirement, Japanese Patent Laid-open Application No. 2002-25979 (Reference Document) discloses a technique for improving the selectivity and the opening characteristic, in which, by using a parallel plate type plasma processing apparatus including a lower electrode and an upper electrode facing the lower electrode in parallel, a semiconductor wafer is mounted on the lower electrode and a plasma etching is performed by using an etching gas containing a fluorocarbon-based gas such as C₅F₈ or C₄F₆, an oxygen gas and a rare gas such as Ar, while regulating a residence time of the etching gas in the chamber by controlling the flow rate of the etching gas to be high in a low pressure.

In the method disclosed in the aforementioned Reference Document, however, it may occur that a desired opening characteristic cannot be obtained under a certain etching condition. For example, though a fine opening characteristic and a high selectivity to the mask can be obtained when the temperature of the semiconductor wafer (the temperature of the lower electrode) is low (e.g., 0° C.), the opening characteristic becomes deteriorated if the temperature of the wafer increases, so that an etch stop occurs when the wafer temperature exceeds a specific temperature level. Further, the opening characteristics depend on pattern shapes. That is, while a hole can be sufficiently etched down to the bottom of the oxide film, an etch stop occurs in, e.g., a trench having a line shape.

Though increasing the rare gas or the O₂ gas can be considered as a solution to prevent the etch stop, both attempts would result in deterioration of the selectivity, so they are not preferable.

### SUMMARY OF THE INVENTION

It is, therefore, an object of the present invention to provide a plasma etching method capable of achieving fine opening characteristic and selectivity even in case a certain etching condition which may cause a low opening characteristic.

Further, it is another object of the present invention to provide a computer readable storage medium for storing therein a control program for executing the plasma etching method.

In accordance with an aspect of the present invention, there is provided a plasma etching method which is performed by using a plasma etching apparatus including a vacuum-evacuable processing chamber having therein a lower electrode serving as a mounting table for a substrate and an upper electrode disposed to face the lower electrode, the plasma etching apparatus performing a plasma etching by converting a processing gas supplied in the processing chamber into a plasma by means of applying a high frequency power of a relatively high frequency level for plasma generation to the upper or the lower electrode and also applying a high frequency power of a relatively low frequency level for bias to the lower electrode. The plasma etching method includes the steps of: generating a plasma of a processing gas containing CₓF_{y} (x, y are integers equal to or greater than 1), a rare gas and O₂ by applying a high frequency power to the upper or the lower electrode while the processing gas is being supplied into the processing chamber; and etching an oxide film formed on the substrate through a mask layer while applying a high frequency power for bias to the lower electrode. In this plasma etching method, when a certain etching condition is likely to cause a low etching opening characteristic, a DC voltage is applied to the upper electrode, to thereby obtain a fine opening characteristic.

In accordance with another aspect of the present invention, there is provided a plasma etching method, which is performed by using a plasma etching apparatus including a vacuum-evacuable processing chamber having therein a lower electrode serving as a mounting table for a substrate, and an upper electrode disposed to face the lower electrode, the plasma etching apparatus performing a plasma etching by converting a processing gas supplied in the processing chamber into a plasma by means of applying a high frequency power for both plasma generation and bias generation to the lower electrode. In the plasma etching method, an oxide film formed on the substrate is etched through a mask layer by applying a high frequency power for both plasma generation and bias generation to the lower electrode while a processing gas containing CₓF_{y} (x, y are integers equal to or greater than 1), a rare gas and O₂ is being supplied into the processing chamber. In the plasma etching method, when a certain etching condition is likely to cause a low etching opening characteristic, a DC voltage is applied to the upper electrode, to thereby obtain a fine opening characteristic.

The certain etching condition may be a condition on a temperature of the substrate and the temperature causing the low opening characteristic may be equal to or higher than about 40° C.

Further, the certain etching condition may be a condition on a shape of an etching pattern and the etching pattern may include a line shape causing the low opening characteristics. In addition, it is preferable to etch down to a depth equal to or greater than a specific value when the etching pattern includes a line shape and a hole shape.

Further, it is preferable that x of the CₓF_{y} is 4 or greater and y is 6 or greater, and, more specifically, the CₓF_{y} is one of C₄F₆, C₅F₈ and C₄F₈ or a gaseous mixture containing two or more species selected from them. Moreover, the rare gas is Ar, Xe, or a gaseous mixture of Ar and Xe.

The present invention provides a computer readable-storage medium for storing therein a computer-executable control program for controlling a plasma etching apparatus including a vacuum-exhaustible processing chamber, a lower electrode serving as a mounting table for a substrate and an upper electrode disposed to face the lower electrode, and performing a plasma etching by converting a processing gas supplied in the processing chamber into a plasma by means of applying a high frequency power of a relatively high frequency level for plasma generation to the upper or the lower electrode and also applying a high frequency power of a relatively low frequency level for bias generation to the lower electrode, or by applying a high frequency power for both plasma generation and bias generation to the lower electrode, wherein, when executed, the control program controls the plasma etching apparatus on a computer to perform the above plasma etching methods.

In accordance with the present invention, an etching having a high selectivity is possible by the steps of: generating a plasma of a processing gas including CₓF_{y} (x, y are integers equal to or greater than 1), a rare gas and O₂ by applying a high frequency power to the upper or the lower electrode while the processing gas is being supplied and etching an oxide film formed on the substrate through a photoresist mask layer while applying a high frequency power for bias generation to the lower electrode. Further, when a certain etching condition is likely to cause a low etching opening characteristic, a DC voltage is applied to the upper electrode, to thereby obtain both of a fine opening characteristic and selectivity.

### BRIEF DESCRIPTION OF THE DRAWINGS

The above and other objects and features of the present invention will become apparent from the following description of embodiments given in conjunction with the accompanying drawings, in which:

FIG. 1 is a schematic cross sectional view showing an exemplary plasma etching apparatus used in performing plasma etching methods in accordance with embodiments of the present invention;

FIG. 2 sets forth a circuit diagram to show a configuration of a matching unit connected to a first high frequency power supply of the plasma etching apparatus shown in FIG. 1;

FIG. 3 depicts a cross sectional view to show a structure of a semiconductor wafer W used in a first embodiment of the present invention;

FIG. 4 provides a diagram to explain an etch stop occurring when the temperature of the semiconductor wafer is increased;

FIG. 5 presents a cross sectional view showing a state resulted by applying a DC voltage to an upper electrode at a temperature where the etch stop occurs as in FIG. 4;

FIG. 6 offers a schematic diagram to explain a mechanism of improving an opening characteristic of etching through an application of a DC voltage;

FIG. 7 is a diagram showing a variation of V_{dc} and a plasma sheath thickness when a DC voltage is applied to the upper electrode of the etching apparatus shown in FIG. 1;

FIGS. 8A to 8C provide schematic views to show experimental results of opening characteristics for the comparison of two cases of varying the temperature of the semiconductor wafer and applying a DC voltage;

FIG. 9 presents a diagram to explain definitions of a flat and a facet;

FIG. 10 is a cross sectional view showing a structure of a semiconductor wafer W used in a second embodiment of the present invention;

FIG. 11 sets forth a cross sectional view to describe a difference between opening characteristics of a hole and those of a trench;

FIG. 12 depicts a cross sectional view to show respective states of the hole and the trench after etching an oxide film by applying a DC voltage to the upper electrode;

FIGS. 13A and 13B provide schematic views to explain experimental results of opening characteristics of a hole and a trench for the comparison of two cases of applying and not applying a DC voltage to the upper electrode;

FIG. 14 is a schematic diagram showing another type of plasma etching apparatus applicable to the embodiments of the present invention; and

FIG. 15 is a schematic diagram showing still another type of plasma etching apparatus applicable to the embodiments of the present invention.

### DETAILED DESCRIPTION OF THE EMBODIMENTS

Hereinafter, embodiments of the present invention will be described in detail with reference to the accompanying drawings.

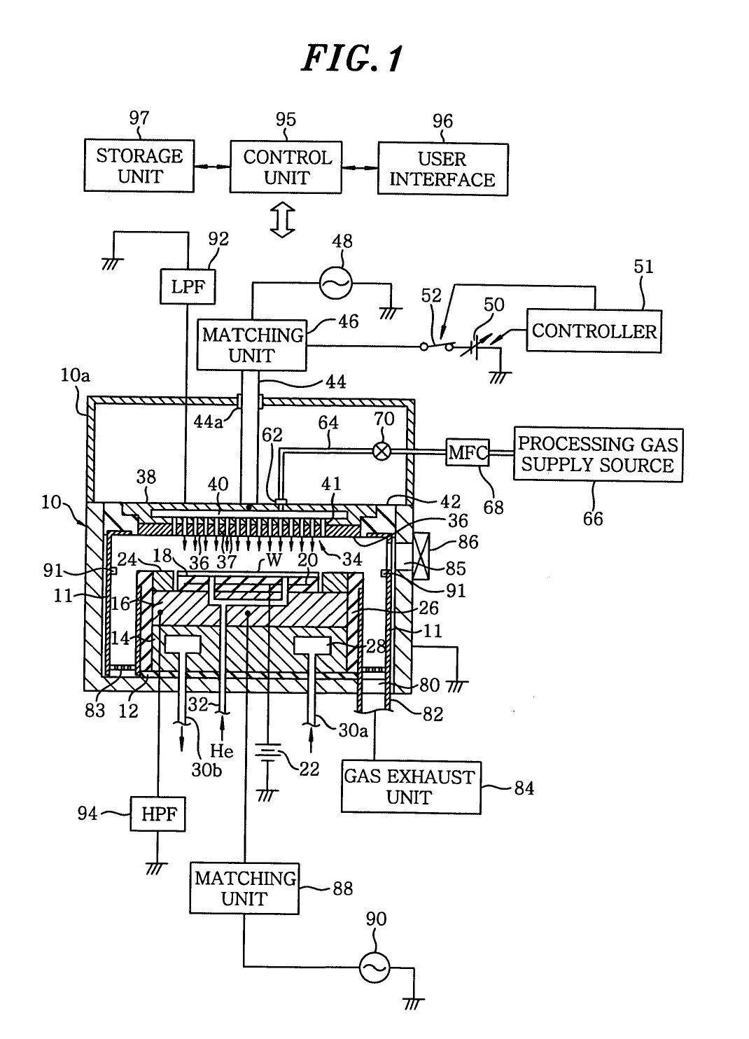

FIG. 1 provides a schematic cross sectional view to show an exemplary plasma etching apparatus used in performing plasma etching methods in accordance with embodiments of the present invention.

The plasma etching apparatus is configured as a capacitively coupled parallel plate type plasma etching apparatus having a substantially cylindrical chamber (processing vessel) 10 made of, e.g., aluminum of which a surface is anodically oxidized. The processing chamber 10 is frame grounded.

A columnar susceptor support 14 is disposed at a bottom portion of the chamber 10 via an insulating plate 12 made of ceramic or the like. Further, a susceptor 16 made of, e.g., aluminum is disposed on the susceptor support 14. The susceptor 16 serves as a lower electrode, while mounting thereon a substrate to be processed, e.g., a semiconductor wafer W.

Provided on top of the susceptor 16 is an electrostatic chuck 18 for attracting and holding the semiconductor wafer W with a help of an electrostatic force. The electrostatic chuck 18 is structured to have an electrode 20 made of a conductive film sandwiched between a pair of insulating layers or insulating sheets. A DC power supply 22 is connected to the electrode 20. The semiconductor wafer W is electrostatically attracted and held to the electrostatic chuck 18 by the electrostatic force such as a Coulomb force generated by a DC voltage applied from the DC power supply 22.

Further, disposed on the periphery of the top surface of the susceptor 16 to surround the electrostatic chuck 18 (semiconductor wafer W) is a focus ring (calibration ring) 24 made of, e.g., silicon, for improving etching uniformity. A cylindrical inner wall member 26 made of, e.g., quartz is disposed on lateral surfaces of the susceptor 16 and the susceptor support 14.

A coolant passage 28 is provided inside the susceptor support 14 circumferentially, for example. A coolant, e.g., cooling water, of a specific temperature is supplied from a chiller unit (not shown) located at outside into the coolant passage 28 through lines 30a and 30b to be circulated therein, whereby a processing temperature of the semiconductor wafer W on the susceptor 16 can be controlled by controlling the temperature of the coolant.

Moreover, a thermally conductive gas, e.g., He gas, is supplied from a thermally conductive gas supply unit (not shown) into a space between the top surface of the electrostatic chuck 18 and the backside of the semiconductor wafer W through a gas supply line 32.

An upper electrode 34 is installed above the susceptor 16 serving as the lower electrode to face the susceptor 16 in parallel. A space between the upper and lower electrodes 34, 16 becomes a plasma generation space. The upper electrode 34 forms a facing surface, i.e., a surface being in contact with the plasma generation space while facing the semiconductor wafer W on the susceptor 16.

The upper electrode 34 is held by an insulating shield 42 at a ceiling portion of the chamber 10. The upper electrode 34 includes an electrode plate 36 and an electrode support 38. The electrode plate 36 forms the facing surface to the susceptor 16 and is provided with a plurality of injection openings 37. The electrode support 38 holds the electrode plate 36 such that the electrode plate 36 can be detachably attached to the electrode support 38. The electrode support 38 of a water cooling type is made of a conductive material, e.g., aluminum of which the surface is anodically oxidized. Preferably, the electrode plate 36 is a low-resistance conductor or semiconductor of a low Joule heat. Meanwhile, in order to strengthen a photoresist, the electrode plate 36 is preferably made of a material containing silicon. Thus, the electrode plate 36 is preferably made of silicon or SiC. A gas diffusion space 40 is provided in the electrode support 38. A plurality of gas holes 41 extends downwards from the gas diffusion space 40 to communicate with the gas injection openings 37.

A gas inlet opening 62 is formed in the electrode support 38 to introduce a processing gas into the gas diffusion space 40. A gas supply line 64 is connected to the gas inlet opening 62, and a processing gas supply source 66 is connected to the gas supply line 64. A mass flow controller (MFC) 68 and a closing/opening valve 70 are sequentially provided from the upstream side in the gas supply line 64 (here, an FCS can be used instead of the MFC). Further, a processing gas for etching, which is fed from the processing gas supply source 66, flows through the gas supply line 64 into the gas diffusion space 40. The processing gas passes through the gas holes 41 and the gas injection openings 37 to be injected into the plasma generating space in a shower shape. That is, the upper electrode 34 functions as a shower head for supplying the processing gas.

A first high-frequency power supply 48 is electrically connected to the upper electrode 34 via a matching unit 46 and a power supply rod 44. The first high-frequency power supply 48 outputs a high frequency power of 10 MHz or higher, e.g., about 60 MHz. The matching unit 46 matches a load impedance to an internal (or output) impedance of the first high-frequency power supply 48, and serves to render the output impedance of the first high-frequency power supply 48 and the load impedance be seemingly matched to each other when a plasma is generated in the chamber 10. An output terminal of the matching unit 46 is connected to the top end of the power supply rod 44.

Meanwhile, a variable DC power supply 50, as well as the first high-frequency power supply 48, is electrically connected to the upper electrode 34. The variable DC power supply 50 may be a bipolar power supply. Specifically, the variable DC power supply 50 is connected to the upper electrode 34 via the matching unit 46 and the power supply rod 44. The power feed of the variable DC power supply 50 can be controlled by an on/off switch 52. The polarity, current and voltage of the variable DC power supply 50 and the on/off operation of the on/off switch 52 are controlled by a controller 51.

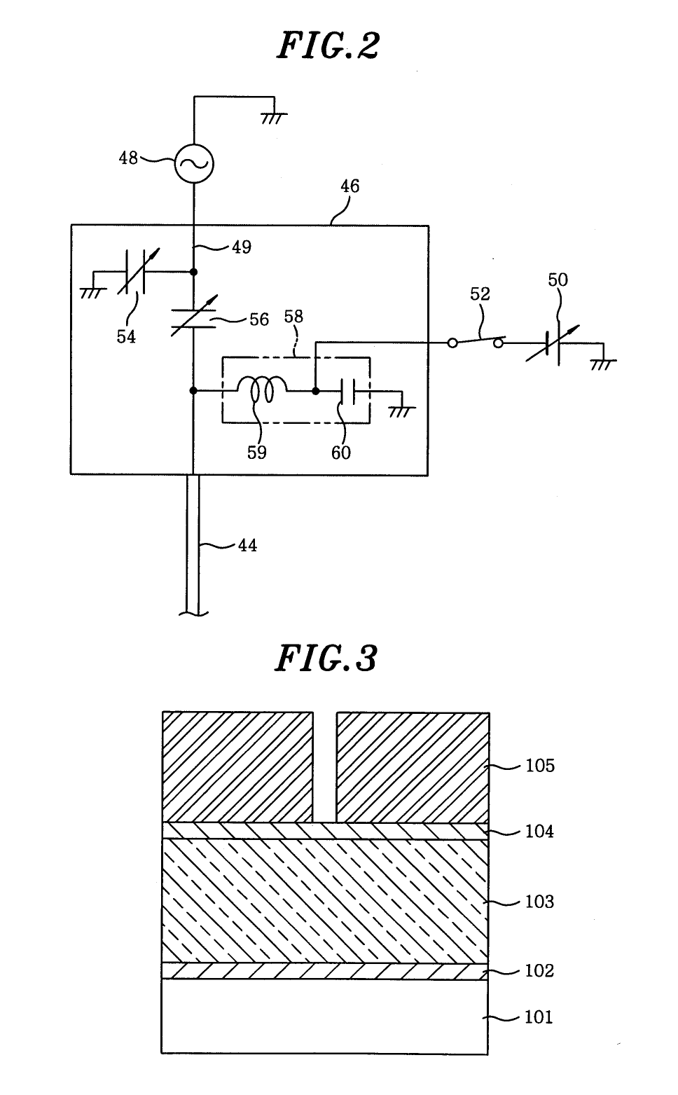

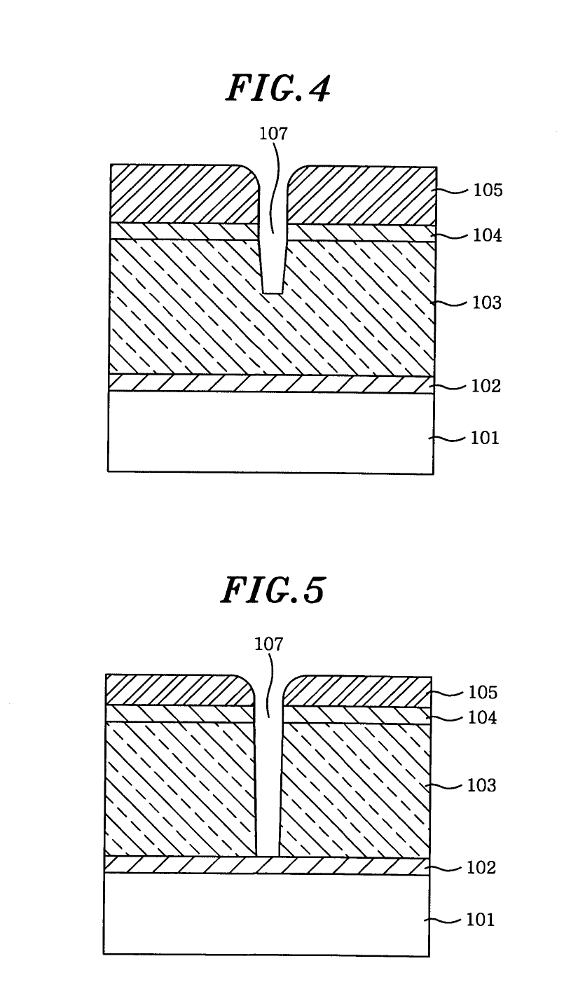

As shown in FIG. 2, the matching unit 46 has a first variable capacitor 54 and a second variable capacitor 56, and functions as described above by using the first and second variable capacitors 54 and 56. The first variable capacitor 54 is branched from a power feed line 49 of the first high-frequency power supply 48, and the second variable capacitor 56 is provided at a downstream side of the branching point in the power feed line 49. Further, a filter 58 is provided in the matching unit 46 to trap a high frequency (e.g., 60 MHz) from the first high-frequency power supply 48 and a high frequency (e.g., 2 MHz) from a second high-frequency power supply to be described later, thus allowing a DC voltage current (hereinafter, referred to as “DC voltage”) to be efficiently supplied to the upper electrode 34. That is, the variable DC power supply 50 is connected through the filter 58 to the power feed line 49. The filter 58 includes a coil 59 and a capacitor 60, and the high frequency from the first high-frequency power supply 48 and the high frequency from the second high-frequency power supply are trapped by the coil 59 and the capacitor 60.

A cylindrical ground conductor 10a extends upwards from a sidewall of the chamber 10 to be located at a position higher than the upper electrode 34. The ceiling wall of the cylindrical ground conductor 10a is electrically insulated from the power supply rod 44 by a tubular insulation member 44a.

The second high-frequency power supply 90 is electrically connected through a matching unit 88 to the susceptor 16 serving as the lower electrode. When a high-frequency power is supplied from the second high-frequency power supply 90 to the susceptor 16, ions are attracted to the semiconductor wafer W. The second high-frequency power supply 90 outputs a high frequency power of a range from 300 KHz to 13.56 MHz, e.g., 2 MHz. The matching unit 88 matches a load impedance to an internal (or output) impedance of the second high-frequency power supply 90, and renders the internal impedance of the second high-frequency power supply 90 and the load impedance be seemingly matched to each other when a plasma is generated in the chamber 10.

A low pass filter (LPF) 92 is electrically connected to the upper electrode 34 for passing the high frequency (e.g., 2 MHz) from the second high-frequency power supply 90 to the ground, without allowing the high frequency (e.g., 60 MHz) from the first high-frequency power supply 48 to pass therethrough. Although the LPF 92 preferably includes an LR filter or an LC filter, it may include a single conducting wire capable of applying sufficiently high reactance to the high frequency (60 MHz) from the first high-frequency power supply 48. Meanwhile, electrically connected to the susceptor 16 is a high pass filter (HPF) 94 for passing the high frequency (60 MHz) from the first high-frequency power supply 48 to the ground.

A gas exhaust port 80 is provided in the bottom of the chamber 10, and a gas exhaust unit 84 is connected to the gas exhaust port 80 through a gas exhaust line 82. The gas exhaust unit 84 has a vacuum pump such as a turbo-molecular pump, and can depressurize the inside of the chamber 10 to a desired vacuum level. Further, a loading/unloading port 85, through which the semiconductor wafer W is loaded and unloaded, is provided in the sidewall of the chamber 10. The loading/unloading port 85 can be opened and closed by a gate valve 86. Further, a deposition shield 11 is detachably installed at the inner wall of the chamber 10 so as to prevent etching byproducts (deposits) from being attached to the chamber 10. That is, the deposition shield 11 serves as a chamber wall. The deposition shield 11 is also provided on the outer surface of the inner wall member 26. A gas exhaust plate 83 is provided at a lower portion of the chamber 10 between the deposition shield 11 installed at the inner wall of the chamber 10 and the deposition shield 11 disposed at the inner wall member 26. The deposition shield 11 and the gas exhaust plate 83 can be appropriately formed by covering an aluminum material with ceramic such as Y₂O₃.

Further, a conductive member (GND block) 91 DC-connected to the ground is provided to a portion of the deposition shield 11 forming the chamber inner wall at a height position substantially identical with the height of the wafer W. With this configuration, an abnormal discharge can be prevented.

Each component of the plasma etching apparatus is connected to and controlled by a control unit (for controlling the whole components) 95. Further, a user interface 96 is connected to the control unit 95, wherein the user interface 96 includes, e.g., a keyboard for a process manager to input a command to operate the plasma processing apparatus, a display for showing an operational status of the plasma processing apparatus and the like.

Moreover, connected to the control unit 95 is a storage unit 97 for storing therein, e.g., control programs to be used in realizing various processes, which are performed in the plasma processing apparatus under the control of the control unit 95 and programs or recipes to be used in operating each component of the plasma processing apparatus to carry out processes in accordance with processing conditions. The recipes can be stored in a hard disk or a semiconductor memory, or can be set at a certain position of the storage unit 97 while being recorded on a portable storage medium such as a CDROM, a DVD and the like.

When a command or the like is received from the user interface 96, the control unit 95 retrieves a necessary recipe from the storage unit 97 and executes the recipe. Accordingly, a desired process is performed in the plasma processing apparatus under the control of the control unit 95.

Hereinafter, there will be described a plasma etching method in accordance with a first embodiment of the present invention, which is performed by the plasma etching apparatus having the aforementioned configuration.

Referring to FIG. 3, a semiconductor wafer W to be processed has an etching stop film 102, an oxide film 103 as a target layer to be etched, a bottom anti-reflection coating (BARC) film 104 and a photoresist film 105 that are sequentially formed on a Si substrate 101. A specific pattern is formed on the photoresist film 105 by photolithography. By using the photoresist film 105 as a mask, the oxide film 103 is etched in the plasma etching apparatus of FIG. 1, so that holes are formed therein.

The oxide film 103 as the target layer to be etched can be, e.g., a film made of tetraethoxysilane (TEOS), a glass film (BPSG or PSG), or the like. The thickness of the oxide film 103 is appropriately set to be in a range, for example, from about 0.5 to 4.0 μm.

The etching stop film 102 is made of SiN or SiC, and its thickness ranges from about 20 to 100 nm. The BARC film 104 is a SiON film or an organic film, and its thickness is in a range from about 20 to 100 nm. The photoresist film 105 is typically an ArF resist of which a thickness ranges from about 100 to 400 nm.

In an etching processing, the gate valve 86 is first opened, and the semiconductor wafer W having the above-described configuration is loaded into the chamber 10 through the loading/unloading port 85 to be mounted on the susceptor 16. Then, a processing gas for etching is supplied from the processing gas supply source 66 into the gas diffusion space 40 at a predetermined flow rate and is then supplied into the chamber 10 via the gas holes 41 and the gas injection openings 37. While the processing gas being supplied into the chamber 10, the chamber 10 is evacuated by the gas exhaust unit 84 so that the internal pressure of the chamber 10 is maintained at a set value within a range from, e.g., about 2.67 to 6.67 Pa (20 to 50 mTorr).

Here, a processing gas containing CₓF_{y} (x, y are integers equal to or greater than 1), a rare gas and O₂ is used to etch the oxide film 103. The CₓF_{y} gas functions for increasing the selectivity by supplying deposits as well as functions as an etchant. It is preferred that x is 4 or greater and y is 6 or greater in the CₓF_{y}. For example, one of C₄F₆, C₅F₈ and C₄F₈ or a gaseous mixture containing two or more species selected from them can be used as the CₓF_{y} gas. Among them, the C₄F₆ gas is particularly preferable. Further, the specific flow rate of the CₓF_{y} gas is preferably set to be in a range from about 10 to 50 mL/min (flow rate conversed in a standard state (sccm)).

The O₂ gas is used to remove redundant deposits, thereby obtaining an etch profile (opening characteristic) (capability to form deep holes without suffering an etch stop) of etching holes. It is preferable to set a flow rate percentage of the O₂ gas to the entire processing gas to be in a range from about 1 to 20%. Specifically, the flow rate of the O₂ gas is preferably set to be in a range from about 10 to 60 mL/min (sccm).

The rare gas functions as a carrier gas or a dilution gas for the CₓF_{y} gas and is added to obtain a balance in the processing gas and, thereby, to control the deposits or fluorine F. It is preferable to add the rare gas such that a flow rate percentage of the rare gas to the entire processing gas ranges from about 60 to 98%. Specifically, the flow rate of the rare gas is preferably set to be in the range from about 350 to 1200 mL/min (sccm). As a rare gas, Ar or Xe, or a gaseous mixture thereof can be appropriately utilized. Further, Kr can also be used as the rare gas.

The processing gas may contain an additional gas besides the CₓF_{y} gas, the rare gas, and the O₂ gas. For example, a hydro-fluorocarbon-based gas, i.e., CHₓF_{y} (x, y are integers equal to or greater than 1) can be included in the processing gas. By adding the hydro-fluorocarbon-based gas, it is possible to etch a nitride film together with the oxide film, in case the nitride film is a base layer.

After the processing gas for etching is introduced into the chamber 10, a high frequency power for plasma generation is applied from the first high-frequency power supply 48 to the upper electrode 34 at a specific power level, and, at the same time, a high frequency power for ion attraction is applied from the second high-frequency power supply 90 to the susceptor 16 as the lower electrode at a certain power level. Further, a DC voltage is applied from the DC power supply 22 to the electrode 20 of the electrostatic chuck 18, whereby the semiconductor wafer W is firmly fixed on the susceptor 16.

The processing gas injected from the gas injection openings 37 formed in the electrode plate 36 of the upper electrode 34 is converted into a plasma by a glow discharge generated between the upper electrode 34 and the susceptor 16 serving as the lower electrode by the high frequency powers applied thereto. The oxide film 103 is etched by radicals or ions in the plasma by using the photoresist film 105 as a mask, whereby holes are formed therein.

Since the high frequency power within a high frequency range (e.g., 10 MHz or higher) is applied to the upper electrode 34, the plasma can be generated at a high density in a desired state, and so it becomes possible to form a high-density plasma even under a lower pressure condition.

Here, in case that the oxide film is etched by using the processing gas only by applying the high frequency power as described above, the opening characteristics (etch profile) of the holes vary depending on the temperature of the semiconductor wafer W. When the temperature of the semiconductor wafer W is low, e.g., 0° C., the etching is performed down to a specific depth. When the temperature of the semiconductor wafer W, however, becomes higher, the opening characteristics of the holes get worse, which may result in a so-called etch stop. The etch stop means that in the course of the target being etched, the etching for an etching hole 107 is stopped due to the low etching characteristics. This is because an attachment coefficient of the deposits becomes changed, and thus, the deposits are introduced into the hole. The state of a low opening characteristic is generated at a temperature of about 20° C. and more frequently at a temperature of about 40° C. as well as under other conditions. That is, when the temperature of the semiconductor wafer W (temperature of the lower electrode) is about 20° C. or greater, particularly, is about 40° C. or greater, the state of a low opening characteristic, such as the etch stop or the like, is developed.

In contrast, in the first embodiment of the present invention, since a DC voltage having a specific polarity and magnitude is applied to the upper electrode 34 from the variable DC power supply 50 when generating plasma, a fine opening characteristic is obtained, and, as shown in FIG. 5, it is possible to form the hole 107 completely through the oxide film 103 to be etched, without suffering an etch stop. At this time, the absolute value of the DC voltage is preferably in a range from about 800 to 1500 V.

The application of the DC voltage to the upper electrode 34 improves the opening characteristic because it makes deposits 109 deposited at a shoulder portion 107a of the hole 107 firmly fixed thereat so as not to be peeled off therefrom, as shown in FIG. 6, thus suppressing a generation of deposits inside the hole 107. That is, the deposits are trapped at the shoulder portion 107a, so they are prevented from reaching the inside of the hole 107. As a result, the opening characteristic (etch profile) of the hole 107 is improved, and the etch stop is prevented. Moreover, by reducing the introduction of the deposits into the hole, an etching rate becomes increased.

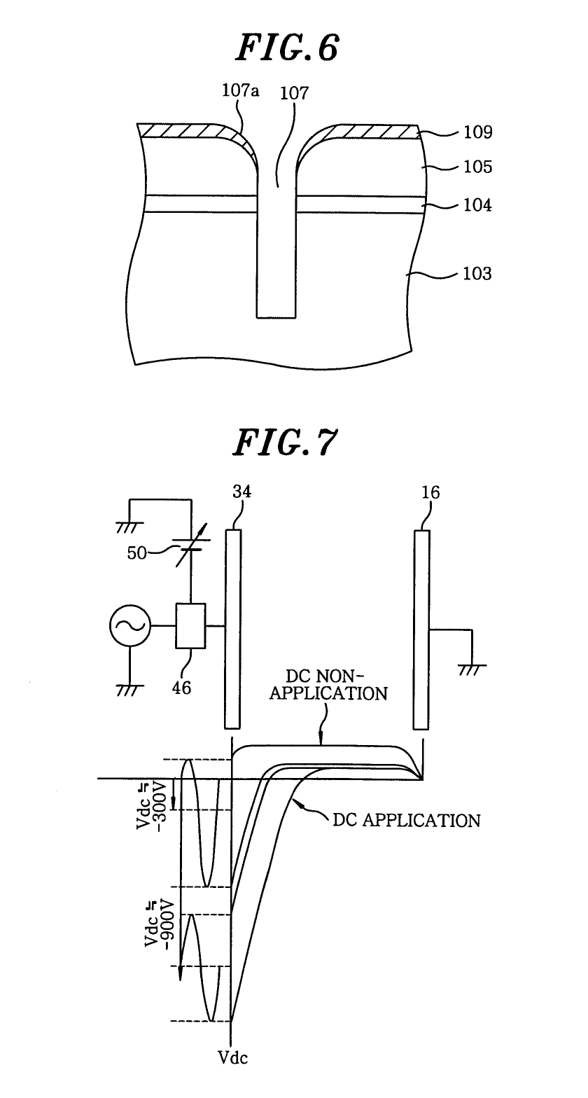

Further, polymers are attached at the upper electrode 34 by the prior etching process, particularly in an etching process in which a high frequency power level to the upper electrode 34 is low. When performing an etching process, if a proper DC voltage is applied to the upper electrode 34, a self bias voltage V_{dc} of the upper electrode 34 can be made higher, that is, the absolute value of the V_{dc} at the surface of the upper electrode 34 can be increased, as shown in FIG. 7. As a result, the polymers attached at the upper electrode 34 are sputtered by the applied DC voltage and are supplied to the semiconductor wafer W to be attached on the photoresist film 105 as deposits. Since these deposits are also fixed at the shoulder portion 107a, the etching of the photoresist film 105 becomes difficult, so that selectivity to the photoresist film 105 is improved.

Below, experiments for investigating the effects of the first embodiment of the present invention and their experimental results will be described.

A sample used in the experiments was obtained by forming, on a Si substrate, a thermally oxidized SiO₂ film having a thickness of 2000 nm as a target oxide film to be etched, forming a BARC film made of an organic film having a thickness of 60 nm on the SiO₂ film, and forming a KrF resist film having a thickness of 600 nm on the BARC film.

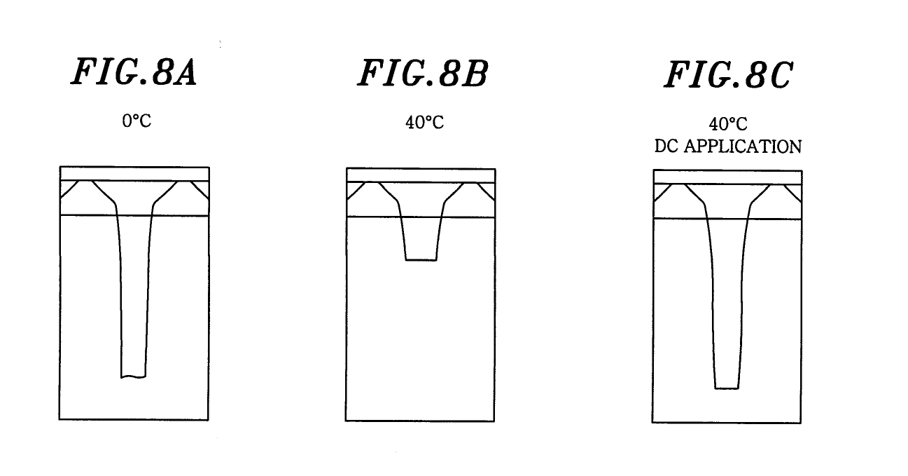

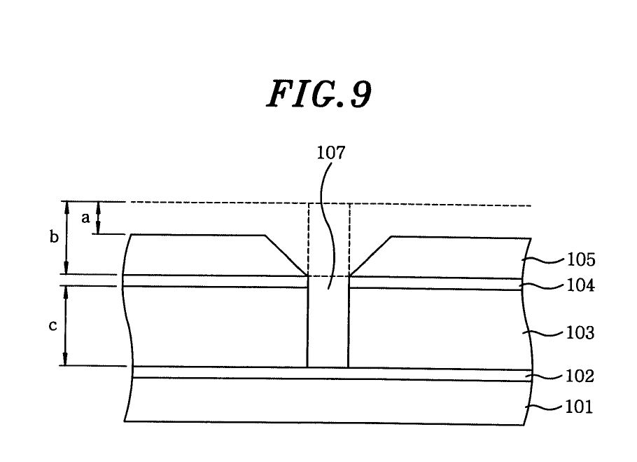

The sample was loaded into the etching apparatus of FIG. 1, and an etching was performed for 180 seconds without applying a DC voltage under the processing conditions that: an internal pressure of the chamber was 3.3 Pa, a high frequency power for the upper electrode was 3000 W, a high frequency power for the lower electrode was 3600 W, a lower electrode temperature was 0° C., and the processing gas included C₄F₆, Ar and O₂ of which respective flow rates were 38 mL/min (sccm), 800 mL/min (sccm) and 50 mL/min (sccm). At the time, a lower electrode Vpp was 2553 V. As a result, a hole having an opening diameter of 0.35 μm and featuring a fine opening characteristic could be obtained, as illustrated in FIG. 8A. At this time, an etching rate was 566 nm/min, and as an etching selectivity to the photoresist film, a flat was 11.3 and a facet was 5.8. Referring to FIG. 9, the flat is c/a and the facet is c/b.

Then, the lower electrode temperature was raised up to 40° C., and an etching was performed under the same processing conditions as those for the former experiment. As a result, an etch stop occurred during the etching, as shown in FIG. 8B.

Then, the lower electrode temperature was maintained at 40° C., and the upper electrode high frequency power was reduced to 1500 W, and a DC voltage of −1000 V was applied to the upper electrode 34. The other processing conditions were identical with those for the former experiments. The reason for reducing the high frequency power for the upper electrode was to coincide the lower electrode Vpp at the time of the DC voltage application, with a voltage level at the time when no DC voltage is applied to the lower electrode. As a result, as shown in FIG. 8C, an etch stop was prevented, and a fine opening characteristic could be obtained. At the time, an etching rate was 585 nm/min, and as an etching selectivity to the photoresist film 105, a flat was 21.9 and a facet was 6.4. Thus, it was confirmed that by applying the DC voltage, the etching rate and the etching selectivity can be improved.

While the first embodiment has been described for the case where the difference of opening characteristics depending on a temperature is solved by the application of the DC voltage to the upper electrode, the difference of opening characteristics depending on a pattern shape can be solved by a second embodiment as follows.

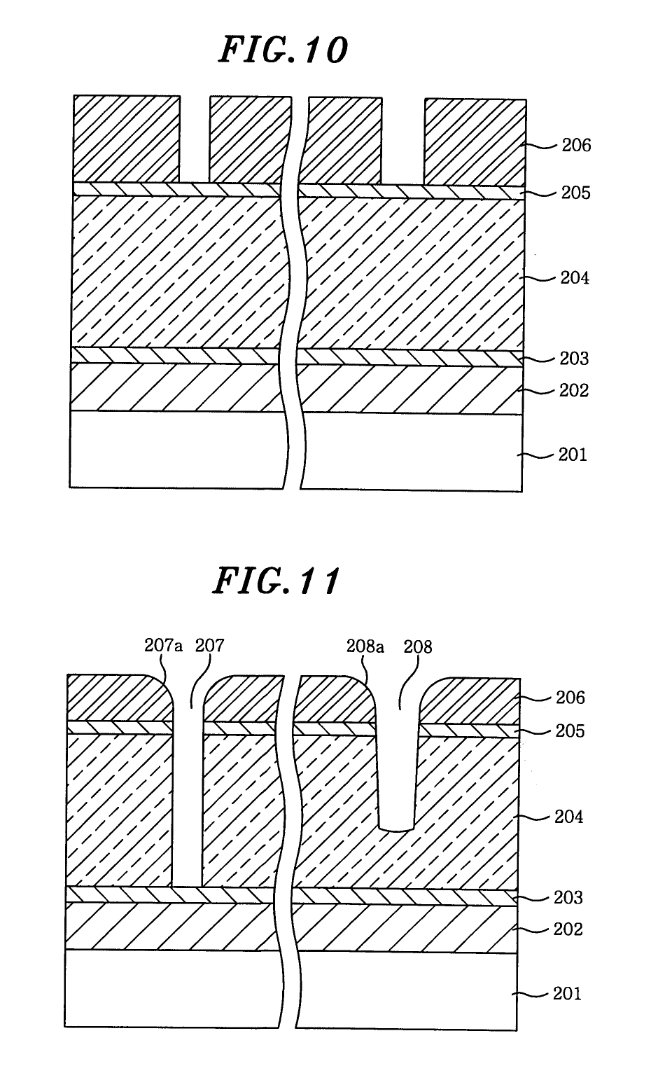

In the second embodiment, as shown in FIG. 10, a semiconductor wafer W used as an object to be processed has a wiring layer 202, an etching stop layer 203, an oxide film 204 (which is a target layer to be etched), a BARC film 205 and a photoresist film 206 that are sequentially formed on a Si substrate 201, wherein a pattern is formed on the photoresist film 206 by photolithography. By using the photoresist film 206 as a mask, the oxide film 204 is etched in the plasma etching apparatus of FIG. 1 so that holes and trenches (line patterns) are formed therein.

The same materials as those used in the first embodiment can be employed as the etching stop film 203, the oxide film 204 to be etched, the BARC film 205 and the photoresist film 206. Further, as the wiring layer 202, a typically employed material such as W, Al, Cu and the like can be used.

When performing the etching, as in the first embodiment, the semiconductor wafer W with the aforementioned configuration is loaded into the chamber 10 to be mounted on the susceptor 16. Then, as in the first embodiment, a processing gas containing CₓF_{y} (x, y are integers equal to or greater than 1), a rare gas and O₂ is introduced from the processing gas supply source 66 into the gas diffusion space 40 at a specific flow rate and is supplied into the chamber 10 through the gas holes 41 and the gas injection openings 37. At the same time, the chamber 10 is evacuated by the gas exhaust unit 84 such that the internal pressure of the chamber 10 is regulated at a set value within a range from, e.g., about 2.67 to 6.67 Pa (20 to 50 mTorr).

After the processing gas for the etching is introduced into the chamber 10, a high frequency power for plasma generation is applied from the first high-frequency power supply 48 to the upper electrode 34 at a specific power level, and, at the same time, a high frequency power for ion attraction is applied from the second high-frequency power supply 90 to the susceptor 16 as the lower electrode at a certain power level. Further, a DC voltage is applied from the DC power supply 22 to the electrode 20 of the electrostatic chuck 18, whereby the semiconductor wafer W is firmly fixed on the susceptor 16.

The processing gas injected from the gas injection openings 37 formed in the electrode plate 36 of the upper electrode 34 is converted into a plasma by a glow discharge generated between the upper electrode 34 and the susceptor 16 serving as the lower electrode by the high frequency powers applied thereto. The oxide film 204 is etched by radicals or ions generated in the plasma by using the photoresist film 206 as a mask, whereby holes and trenches are formed therein.

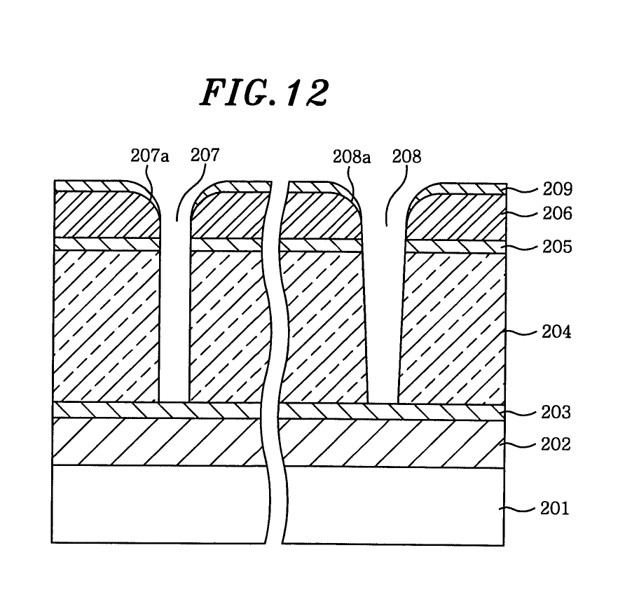

Here, when etching the oxide film with the above processing gas only by applying the high frequency powers, the holes and the trenches have different opening characteristics. That is, the opening characteristics vary depending on the pattern shapes. As illustrated in FIG. 11, a hole 207 is etched with a fine opening characteristic, whereas a trench 208, which is a line shaped pattern, has a low opening characteristic, resulting in a high likelihood that an etch stop occurs. This difference is caused because it is difficult for polymers, which would become deposits, to enter the hole having a pattern of narrow width, whereas it is easy for the polymers to enter the trench having a pattern of wide width. Thus, in case of the trench, more deposits are accumulated therein, and its opening characteristic becomes deteriorated.

In contrast, in the second embodiment of the present invention, since a DC voltage having a specific polarity and magnitude is applied to the upper electrode 34 from the variable DC power supply 50 when generating a plasma, as in the first embodiment, deposits 209 accumulated at a shoulder portion 207a of the hole 207 or at a shoulder portion 208a of the trench 208 are firmly fixed thereat so as not to be peeled off therefrom. Thus, even in case of the trench which tends to readily suffer a deposit generation, the deposits can be reduced, so that the opening characteristic of the trench is improved, and it becomes possible to etch the trench 208 as well as the hole 207, down to the etching stop film 203, as illustrated in FIG. 12. In such case, deposits in the hole 207 and the trench 208 decrease, resulting in an increase in etching rates thereof. Further, since the polymers supplied from the upper electrode 34 are also fixed at the shoulder portions 207a and 207b by applying the DC voltage to the upper electrode 34, an etching of the photoresist film 206 becomes difficult, so that the selectivity to the photoresist film 206 is increased. In the second embodiment, the absolute value of the DC voltage applied to the upper electrode 34 is preferably set to be in a range from about 800 to 1500 V.

Below, experiments for investigating effects of the second embodiment of the present invention and experimental results will be described.

A sample used in the experiments was obtained by forming, on a Si substrate, a SiN film having a thickness of 50 nm as an etching stop layer, forming a BPSG film having a thickness of 1000 nm and a TEOS film having a thickness of 28000 nm as target oxide films to be etched, and forming a KrF resist film having a thickness of 900 nm on the TEOS film.

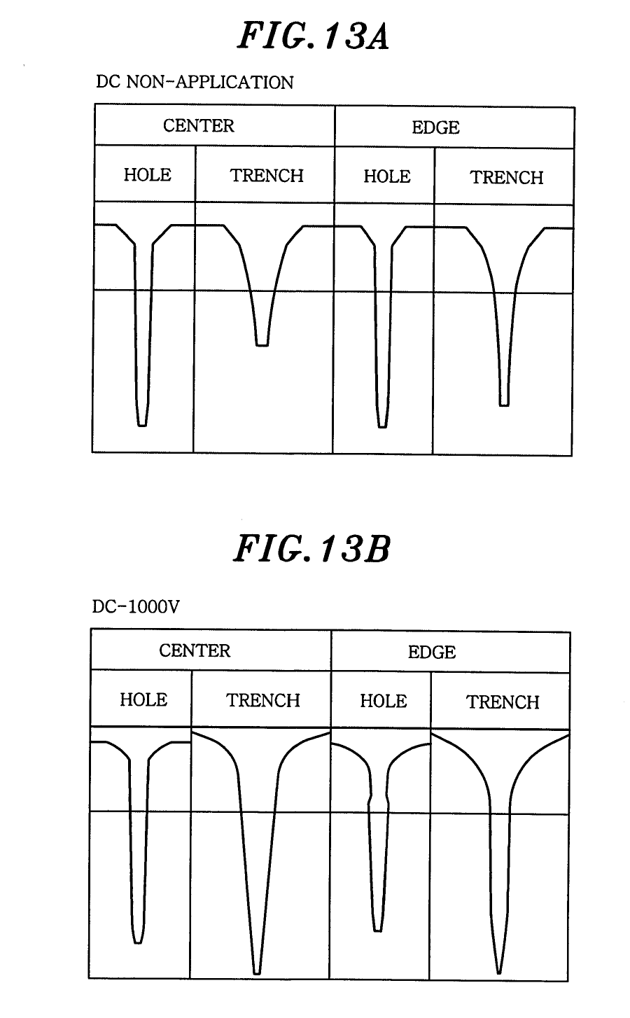

The sample was loaded into the etching apparatus of FIG. 1, and an etching was performed for 240 seconds without applying a DC voltage under the processing conditions that: an internal pressure of the chamber was 33.5 Pa (25 mTorr), a high frequency power for the upper electrode was 3000 W, a high frequency power for the lower electrode was 3600 W, a lower electrode temperature was 0° C., and the processing gas included C₄F₆, Ar and O₂ of which respective flow rates were 38 mL/min (sccm), 800 mL/min (sccm) and 46 mL/min (sccm). As a result, as shown in FIG. 13A, though a hole having a fine opening characteristic was obtained, a trench was given a low opening characteristic. In particular, the opening characteristic of the trench was worse at a wafer center portion and the depth of the trench thereat only reaches the half of the depth of the hole. At that time, as an etching selectivity to the photoresist film, a flat was 15.8 and a facet was 5.5 at a wafer center portion, while a flat was 16.7 and a facet was 6.3 at a wafer edge portion.

Then, to coincide a lower electrode Vpp at the time of the DC voltage application with a voltage level at the time when no DC voltage is applied to the lower electrode, the upper electrode high frequency power was reduced to 1500 W, and a DC voltage of −1000 V was applied to the upper electrode 34. The other processing conditions were identical with those for the former experiment. As a result, as shown in FIG. 13B, the opening characteristic of the trench was improved and the trench reached at a position even deeper than the hole. As the selectivity to the photoresist film, a flat at a wafer center portion could not be measured because the film thickness was increased due to deposits. A facet at the wafer center portion was 7.7. Further, at a wafer edge portion, a flat could not be measured for the same reason, and a facet was 6.4. Thus, it was confirmed that the etching selectivity is increased as a result of the DC voltage application.

Here, it is to be noted that the present invention can be modified in various ways without being limited to the embodiments described above. For example, though the above embodiments have been described for the case of using the photoresist film as a mask, it is also possible to use a hard mask layer together. Further, though the oxide films exemplified in the embodiments are made of TEOS, BPSG or PSG, the materials for the oxide films are not limited thereto. Moreover, the structure of the semiconductor wafer is not limited to the aforementioned examples, either.

In addition, the apparatus to which the present invention is applied is not limited to the one shown in FIG. 1, either. For example, it is possible to use a type in which an upper electrode is divided into a central part and a peripheral part so that high frequency powers applied thereto can be controlled individually. Further, it is also possible to use a plasma etching apparatus of a type in which dual frequency powers are applied to a lower electrode. In this type of apparatus, a high frequency power of, e.g., about 40 MHz for plasma generation is applied from a first high-frequency power supply 48′ to the susceptor 16 which serves as the lower electrode, and a second high frequency power of, e.g., about 2 MHz for ion attraction is concurrently applied to the susceptor 16 from a second high-frequency power supply 90′. As shown in the figure, by connecting the a variable DC power supply 166 to an upper electrode 234 and applying a DC voltage thereto, the same effects as obtained in the above embodiments can be achieved.

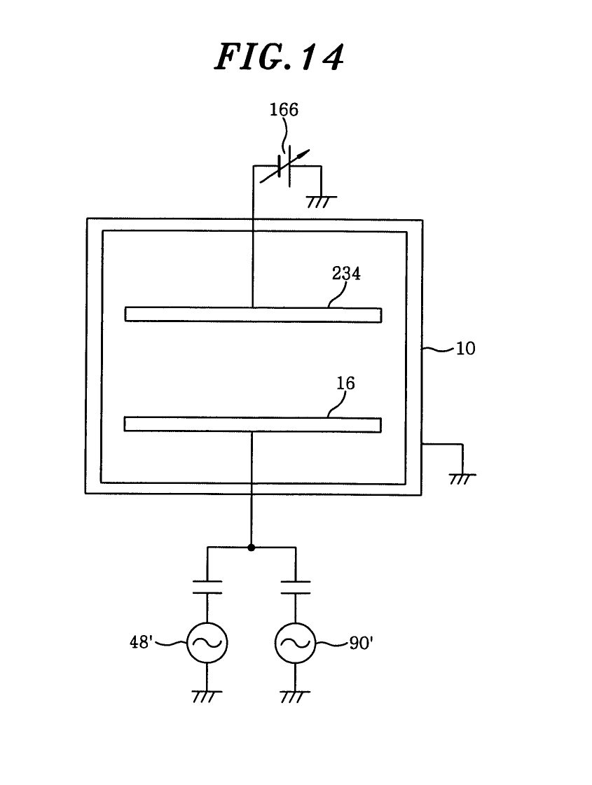

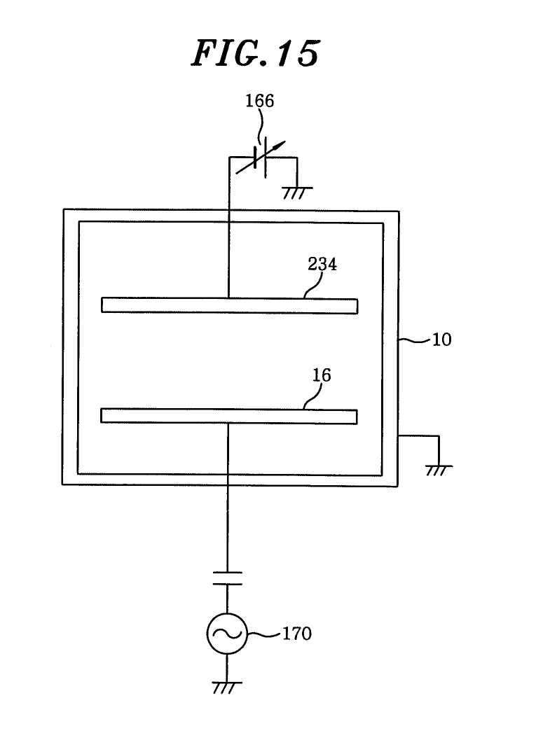

Furthermore, as illustrated in FIG. 15, it is also possible to use an etching apparatus of a type having a high frequency power supply 170 instead of the first high-frequency power supplies 48′ and the second high-frequency power supply 90′ connected to the susceptor 16 in FIG. 14. In such case, a high frequency power of, e.g., about 40 MHz for both plasma generation and bias generation is applied to the susceptor 16, i.e., the lower electrode. As in FIG. 14, by connecting a variable DC power supply 166 to an upper electrode 234 and applying a specific DC voltage thereto, the same effects as obtained in the above experiments can be achieved.

While the invention has been shown and described with respect to the embodiments, it is understood by those skilled in the art that various changes and modifications may be made without departing from the scope of the invention as defined in the following claims.

What is claimed is:

1. A plasma etching method, which is performed by using a plasma etching apparatus including a vacuum-evacuable processing chamber having therein a lower electrode serving as a mounting table for a substrate and an upper electrode disposed to face the lower electrode, the plasma etching apparatus performing a plasma etching by converting a processing gas supplied in the processing chamber into a plasma by means of applying a high frequency power of a relatively high frequency level for plasma generation to the upper or the lower electrode and also applying a high frequency power of a relatively low frequency level for bias to the lower electrode, comprising the steps of:
generating a plasma of a processing gas containing CₓF_{y} (x, y are integers equal to or greater than 1), a rare gas and O₂ by applying a high frequency power to the upper or the lower electrode while the processing gas is being supplied into the processing chamber; and
etching an oxide film formed on the substrate through a mask layer while applying a high frequency power for bias to the lower electrode,
wherein when a certain etching condition is likely to cause a low etching opening characteristic, a DC voltage is applied to the upper electrode, to thereby obtain a fine opening characteristic.

2. A plasma etching method, which is performed by using a plasma etching apparatus including a vacuum-evacuable processing chamber having therein a lower electrode serving as a mounting table for a substrate and an upper electrode disposed to face the lower electrode, the plasma etching apparatus performing a plasma etching by converting a processing gas supplied in the processing chamber into a plasma by means of applying a high frequency power for both plasma generation and bias to the lower electrode, the method comprising the steps of:
etching an oxide film formed on the substrate through a mask layer by applying a high frequency power for both plasma generation and bias generation to the lower electrode while a processing gas containing CₓF_{y} (x, y are integers equal to or greater than 1), a rare gas and O₂ is being supplied into the processing chamber,
wherein when a certain etching condition is likely to cause a low etching opening characteristic, a DC voltage is applied to the upper electrode, to thereby obtain a fine opening characteristic.

3. The plasma etching method of claim 1, wherein the certain etching condition is a condition on a temperature of the substrate.

4. The plasma etching method of claim 2, wherein the certain etching condition is a condition on a temperature of the substrate.

5. The plasma etching method of claim 3, wherein the temperature of the substrate is equal to or higher than about 40° C.

6. The plasma etching method of claim 4, wherein the temperature of the substrate is equal to or higher than about 40° C.

7. The plasma etching method of claim 1, wherein the certain etching condition is a condition on a shape of an etching pattern.

8. The plasma etching method of claim 2, wherein the certain etching condition is a condition on a shape of an etching pattern.

9. The plasma etching method of claim 7, wherein the etching pattern includes a line shape.

10. The plasma etching method of claim 8, wherein the etching pattern includes a line shape.

11. The plasma etching method of claim 7, wherein the etching pattern includes a line shape and a hole shape, and both are etched down to a depth equal to or greater than a specific value.

12. The plasma etching method of claim 8, wherein the etching pattern includes a line shape and a hole shape, and both are etched down to a depth equal to or greater than a specific value.

13. The plasma etching method of claim 1, wherein x of the CₓF_{y} is equal to or greater than 4, while y is equal to or greater than 6.

14. The plasma etching method of claim 2, wherein x of the CₓF_{y} is equal to or greater than 4, while y is equal to or greater than 6.

15. The plasma etching method of claim 13, wherein the CₓF_{y} is one of C₄F₆, C₅F₈ and C₄F₈ or a gaseous mixture containing two or more species selected from them.

16. The plasma etching method of claim 14, wherein the CₓF_{y} is one of C₄F₆, C₅F₈ and C₄F₈ or a gaseous mixture containing two or more species selected from them.

17. The plasma etching method of claim 1, wherein the rare gas is Ar, Xe, or a gaseous mixture of Ar and Xe.

18. The plasma etching method of claim 2, wherein the rare gas is Ar, Xe, or a gaseous mixture of Ar and Xe.

19. A computer readable-storage medium for storing therein a computer-executable control program for controlling a plasma etching apparatus including a vacuum-evacuable processing chamber having therein, a lower electrode serving as a mounting table for a substrate and an upper electrode disposed to face the lower electrode, the plasma processing apparatus performing a plasma etching by converting a processing gas supplied in the processing chamber into a plasma by means of applying a high frequency power of a relatively high frequency level for plasma generation to the upper or the lower electrode and also applying a high frequency power of a relatively low frequency level for bias to the lower electrode,
wherein, when executed, the control program controls the plasma etching apparatus to perform the plasma etching method of claim 1.

20. A computer readable-storage medium for storing therein a computer-executable control program for controlling a plasma etching apparatus including a vacuum-evacuable processing chamber having therein, a lower electrode serving as a mounting table for a substrate and an upper electrode disposed to face the lower electrode, the plasma etching apparatus performing a plasma etching by converting a processing gas supplied in the processing chamber into a plasma by means of applying a high frequency power for both plasma generation and bias to the lower electrode,
wherein, when executed, the control program controls the plasma etching apparatus to perform the plasma etching method of claim 2.
